(19) United States
(12) Patent Application Publication
(10) Pub. No.: US 2026/0212826 A1
(43) Pub. Date: Jul. 23, 2026

(54) SHIFT REGISTER, GATE DRIVING CIRCUIT, DISPLAY PANEL, AND DISPLAY DEVICE

(71) Applicants: Hefei BOE Joint Technology Co., Ltd., Hefei, Anhui (CN); BOE Technology Group Co., Ltd., Beijing (CN); Beijing BOE Technology Development Co., Ltd., Beijing (CN)

(72) Inventors: Xuehuan Feng, Beijing (CN); Yongqian Li, Beijing (CN)

(73) Assignees: Hefei BOE Joint Technology Co., Ltd., Hefei, Anhui (CN); BOE Technology Group Co., Ltd., Beijing (CN); Beijing BOE Technology Development Co., Ltd., Beijing (CN)

(21) Appl. No.: 19/157,764

(22) PCT Filed: Jul. 10, 2024
(86) PCT No.: PCT/CN2024/104668

§ 371 Date: Aug. 19, 2025

(30) Foreign Application Priority Data
Aug. 8, 2023 (CN) 202310993841.6

(51) Int. Cl. G09G 3/3266; G09G 3/36; G11C 19/28

(52) U.S. Cl. CPC G09G 3/3266; G11C 19/28; G09G 3/3677; G09G 2300/0842; G09G 2310/0286; G09G 2310/08; G09G 2320/0257

(57) ABSTRACT

The present disclosure provides a shift register, a gate driving circuit, a display panel, and a display device. In the shift register, a first display input circuit is configured to write a signal of a first voltage terminal into a first pull-up node under the control of a signal of a first display input terminal; a first display shift circuit is configured to write a signal of a first shift signal terminal into a first shift output terminal under the control of a signal of the first pull-up node; a black insertion input circuit is configured to write a signal of a second voltage terminal into the first pull-up node under the control of signals of a first black insertion input terminal, a first control terminal, and a second control terminal; a first black insertion shift circuit is configured to write a signal of a second shift signal terminal into a second shift output terminal under the control of the signal of the first pull-up node; and a first output circuit is configured to write the signal of the first signal terminal into a first output terminal under the control of the signal of the first pull-up node.

### CROSS-REFERENCE TO RELATED APPLICATION

The present disclosure claims the priority of Chinese patent application filed on Aug. 8, 2023 before the CNIPA, China National Intellectual Property Administration with the application number of 202310993841.6, and the title of “SHIFT REGISTER, GATE DRIVING CIRCUIT, DISPLAY PANEL AND DISPLAY DEVICE”, which is incorporated herein in its entirety by reference.

### FIELD

The present disclosure relates to the field of display technologies, and more particularly to a shift register, a gate driving circuit, a display panel and a display device.

### BACKGROUND

In the field of display technologies, especially in an organic light-emitting diode (OLED) display device, a dynamic image smear phenomenon is easily occurred during a switching process of images displayed on a dynamic display screen, that is, when a previous frame of image displayed is switched to a next frame of image displayed, a smear of the previous frame of image may be sensed. In order to overcome the dynamic image smear phenomenon, in the related art, a darkness screen is to be switched to during pixels emitting light, so as to reduce normal display time duration of the pixels, thereby effectively improving the dynamic image smear phenomenon.

### SUMMARY

Embodiments of the present disclosure provide a shift register, a gate driving circuit, a display panel and a display device, which improve the dynamic image smear phenomenon.

In order to achieve the above objectives, following technical solutions are used in the embodiments of the present disclosure.

In an aspect, a shift register is provided. The shift register includes a first scanning unit, where the first scanning unit includes a first display input circuit, a first display shift circuit, a black insertion input circuit, a first black insertion shift circuit and a first output circuit, where
the first display input circuit is electrically connected to a first display input terminal, a first voltage terminal and a first pull-up node, and is configured to write a signal of the first voltage terminal into the first pull-up node under the control of a signal of the first display input terminal;
the first display shift circuit is electrically connected to the first pull-up node, a first shift signal terminal and a first shift output terminal, and is configured to write a signal of the first shift signal terminal into the first shift output terminal under the control of a signal of the first pull-up node;
the black insertion input circuit is electrically connected to a first black insertion input terminal, a first control terminal, a second control terminal, a second voltage terminal and the first pull-up node, and is configured to write a signal of the second voltage terminal into the first pull-up node under the control of signals of the first black insertion input terminal, the first control terminal and the second control terminal;
the first black insertion shift circuit is electrically connected to the first pull-up node, a second shift signal terminal and a second shift output terminal, and is configured to write a signal of the second shift signal terminal into the second shift output terminal under the control of the signal of the first pull-up node; and
the first output circuit is electrically connected to the first pull-up node, a first signal terminal and a first output terminal, and is configured to write a signal of the first signal terminal into the first output terminal under the control of the signal of the first pull-up node.

In some embodiments, the shift register further includes a second scanning unit, where the second scanning unit includes a second display input circuit, a second display shift circuit and a second output circuit, where
the second display input circuit is electrically connected to the first shift output terminal, the first voltage terminal and a second pull-up node, and is configured to write a signal of the first voltage terminal into the second pull-up node under the control of a signal of the first shift output terminal;
the second display shift circuit is electrically connected to the second pull-up node, a third shift signal terminal and a third shift output terminal, and is configured to write a signal of the third shift signal terminal into the third shift output terminal under the control of a signal of the second pull-up node;
the second output circuit is electrically connected to the second pull-up node, a second signal terminal and a second output terminal, and is configured to write a signal of the second signal terminal into the second output terminal under the control of the signal of the second pull-up node; and
the black insertion input circuit is electrically connected to the first pull-up node and the second pull-up node at the same time, and is further configured to write a signal at the second pull-up node.

In some embodiments, the black insertion input circuit includes a first black insertion input circuit and a second black insertion input circuit, where the first black insertion input circuit is electrically connected to the first pull-up node, and is configured to write a signal at the first pull-up node; and the second black insertion input circuit is electrically connected to the second pull-up node, and is configured to write a signal at the second pull-up node.

In some embodiments, at a same time, the signal written by the first black insertion input circuit at the first pull-up node is the same as the signal written by the second black insertion input circuit at the second pull-up node.

In some embodiments,
the first black insertion input circuit is electrically connected to the first black insertion input terminal, the first control terminal, the second control terminal, the second voltage terminal and the first pull-up node, and is configured to write the signal of the second voltage terminal into the first pull-up node under the control of the signals of the first black insertion input terminal, the first control terminal and the second control terminal; and
the second black insertion input circuit is electrically connected to the first black insertion input terminal, the first control terminal, the second control terminal, the second voltage terminal and the second pull-up node, and is configured to write the signal of the second voltage terminal into the second pull-up node under the control of the signals of the first black insertion input terminal, the first control terminal and the second control terminal.

In some embodiments, the first black insertion input circuit includes a first sub-circuit and a second sub-circuit, where
the first sub-circuit is electrically connected to the first black insertion input terminal, the first control terminal, the second voltage terminal and a first node, and is configured to write the signal of the second voltage terminal into the first node under the control of signals of the first black insertion input terminal and the first control terminal;
the second sub-circuit is electrically connected to the second control terminal, the first node and the first pull-up node, and is configured to write a signal of the first node into the first pull-up node under the control of the signal of the second control terminal; and
the second black insertion input circuit is electrically connected to the first node, the second control terminal and the second pull-up node, and is configured to write the signal of the first node into the second pull-up node under the control of the signal of the second control terminal.

In some embodiments, the second black insertion input circuit includes a first sub-circuit and a second sub-circuit, where
the first sub-circuit is electrically connected to the first black insertion input terminal, the first control terminal, the second voltage terminal and a second node, and is configured to write the signal of the second voltage terminal into the second node under the control of signals of the first black insertion input terminal and the first control terminal;
the second sub-circuit is electrically connected to the second control terminal, a first node and the second pull-up node, and is configured to write a signal of the first node into the second pull-up node under the control of the signal of the second control terminal; and
the first black insertion input circuit is electrically connected to the first node, the second control terminal and the first pull-up node, and is configured to write the signal of the first node into the first pull-up node under the control of the signal of the second control terminal.

In some embodiments, the first black insertion input circuit is electrically connected to the first black insertion input terminal, the first control terminal, the second control terminal, the second voltage terminal and the first pull-up node, and is configured to write the signal of the second voltage terminal into the first pull-up node under the control of the signals of the first black insertion input terminal, the first control terminal and the second control terminal;
the second black insertion input circuit is electrically connected to the second black insertion input terminal, the first control terminal, the second control terminal, the second voltage terminal and the second pull-up node, and is configured to write the signal of the second voltage terminal into the second pull-up node under the control of signals of the second black insertion input terminal, the first control terminal and the second control terminal; and
the second scanning unit further includes a second black insertion shift circuit, where the second black insertion shift circuit is electrically connected to the second pull-up node, a fourth shift signal terminal and a fourth shift output terminal, and is configured to write a signal of the fourth shift signal terminal into the fourth shift output terminal under the control of the signal of the second pull-up node.

In some embodiments, the second voltage terminal is electrically connected to the second control terminal, or the second voltage terminal is disconnected from the second control terminal.

In some embodiments, the first sub-circuit includes a third sub-circuit and a fourth sub-circuit, where
the third sub-circuit is electrically connected to the first black insertion input terminal, the first control terminal and the second node, and is configured to write the signal of the first black insertion input terminal into the second node under the control of the signal of the first control terminal; and
the fourth sub-circuit is electrically connected to the second node, the second voltage terminal, the second control terminal and the first pull-up node, and is configured to write the signal of the second voltage terminal into the first pull-up node under the control of signals of the second node and the second control terminal.

In some embodiments, the first scanning unit further includes a first black insertion reset circuit, where the first black insertion reset circuit is electrically connected to the first pull-up node, the second node, a black insertion reset control terminal and a first reset voltage terminal, and is configured to write a signal of the first reset voltage terminal into the first pull-up node under the control of signals of the second node and the black insertion reset control terminal.

In some embodiments, the first scanning unit further includes a first pull-down circuit and a first noise reduction circuit, where
the first pull-down circuit is electrically connected to the first pull-up node, a first reset voltage terminal and a first pull-down node, and is configured to write a signal of the first reset voltage terminal into the first pull-down node under the control of the signal of the first pull-up node; and
the first noise reduction circuit is electrically connected to the first pull-down node, the first reset voltage terminal and the second shift output terminal, and is configured to write the signal of the first reset voltage terminal into the second shift output terminal under the control of a signal of the first pull-down node.

In some embodiments, the shift register further includes a fifth reset circuit, where the fifth reset circuit is electrically connected to the second control terminal, the second node, the first reset voltage terminal and the first pull-down node, and is configured to write the signal of the first reset voltage terminal into the first pull-down node under the control of signals of the second node and the second control terminal.

In another aspect, a gate driving circuit is provided. The gate driving circuit includes a plurality of shift registers, where the plurality of shift registers are arranged in cascade.

In some embodiments, the plurality of the shift registers include a first shift register and a second shift register which are arranged in cascade, where when each of the plurality of the shift registers includes a first display shift circuit, a second display shift circuit and a first black insertion shift circuit, a second shift output terminal of the first shift register is electrically connected to a first black insertion input terminal of the second shift register, and a third shift output terminal of the first shift register is connected to a first display input terminal of the second shift register.

In some embodiments, the plurality of the shift registers include a first shift register and a second shift register which are arranged in cascade, where when each of the plurality of the shift registers includes a first display shift circuit, a second display shift circuit, a first black insertion shift circuit and a second black insertion shift circuit, a third shift output terminal of the first shift register is electrically connected to a first display input terminal of the second shift register, a second shift output terminal of the first shift register is electrically connected to a first black insertion input terminal of the second shift register, and a fourth shift output terminal of the first shift register is electrically connected to a second black insertion input terminal of the second shift register.

In some embodiments, the gate driving circuit includes a plurality of gate lines, and the first scanning unit includes a plurality of first output circuits, where first output terminals of the plurality of first output circuits are respectively electrically connected to different gate lines; and/or, the second scanning unit includes a plurality of second output circuits, where second output terminals of the plurality of second output circuits are respectively electrically connected to different gate lines, where the first output terminals and the second output terminals are electrically connected to different gate lines.

In some embodiments, the first scanning unit includes four first output circuits, and the second scanning unit includes four second output circuits.

In still another aspect, a display panel is provided. The display panel includes the above gate driving circuit.

In yet another aspect, a display device is provided. The display device includes the above display panel.

In the shift register, the gate driving circuit, the display panel and the display device of the embodiments of the present disclosure, the first black insertion input circuit, the first black insertion shift circuit, the first display input circuit, the first display shift circuit and the first output circuit are simultaneously provided, where the first output circuit is electrically connected to a pixel driving circuit P1 to control the pixel driving circuit P1 to write an image data signal and a black data signal; the first black insertion input circuit, the first output circuit and the first black insertion shift circuit constitute a black insertion driving module to realize black insertion driving, and the first display input circuit, the first output circuit and the first display shift circuit constitute a display driving module to realize display driving; the first black insertion shift circuit may be used to realize a cascade of different black insertion driving modules, and the first display shift circuit may be used to realize a cascade of different display driving modules, that is, the first black insertion shift circuit is provided separately to realize the cascade of different black insertion driving modules. Compared with the related art in which the cascade of black insertion driving modules is realized by multiplexing the display shift circuit and/or the display output circuit, the number of shift registers spanned by the first black insertion shift circuit in the embodiments of the present disclosure when cascaded is less, and thus the wiring difficulty is lower.

### BRIEF DESCRIPTION OF THE DRAWINGS

In order to more clearly explain technical solutions in the embodiments of the present disclosure or the related art, accompanying drawings needed in the description of the embodiments or the related art will be briefly introduced below. Obviously, the accompanying drawings described below are only some embodiments of the present disclosure. For a person skilled in the art, other accompanying drawings may be obtained according to these accompanying drawings without creative labor.

FIG. 1 exemplarily illustrates a front structure of a display device.

FIG. 2 exemplarily illustrates a structural diagram of a display panel.

FIG. 3 exemplarily illustrates a circuit diagram of a pixel driving circuit.

FIG. 4 exemplarily illustrates a structural diagram of another display panel.

FIG. 5 exemplarily illustrates a signal timing diagram of a pixel driving circuit shown in FIG. 3.

FIG. 6 exemplarily illustrates a circuit block diagram of a shift register.

FIG. 7 exemplarily illustrates a circuit diagram of a first scanning unit.

FIG. 8 exemplarily illustrates a structural block diagram of another shift register.

FIG. 9 exemplarily illustrates a structural block diagram of another shift register.

FIG. 10 exemplarily illustrates a circuit diagram of a shift register.

FIG. 11 exemplarily illustrates a circuit diagram of a first black insertion input circuit.

FIG. 12 exemplarily illustrates a circuit diagram of a second black insertion input circuit.

FIG. 13 exemplarily illustrates a circuit diagram of a shift register.

FIG. 14 exemplarily illustrates a circuit diagram of a first black insertion input circuit.

FIG. 15 exemplarily illustrates a block diagram of a gate driving circuit.

FIG. 16 exemplarily illustrates a timing diagram of a gate driving circuit.

FIG. 17 exemplarily illustrates a circuit diagram of a shift register.

FIG. 18 exemplarily illustrates a circuit diagram of another shift register.

### DETAILED DESCRIPTION

In order to make a person skilled in the art better understand the technical solutions of the present disclosure, the present disclosure will be further described in detail below with reference to the accompanying drawings and specific embodiments.

Unless otherwise defined, technical terms or scientific terms used in the present disclosure should have ordinary meanings as understood by a person skilled in the art to which the present disclosure belongs. The terms “first”, “second” or similar words used in the present disclosure do not indicate any order, quantity or importance, but are only used to distinguish different components. Similarly, the terms “a”, “an”, “the” or similar words do not indicate a limitation of quantity, but rather indicate the existence of at least one. The terms “include”, “comprise” or similar words indicate that elements or objects stated before them encompass the elements or objects and equivalents thereof listed after them, but do not exclude other elements or objects. The terms “connecting”, “connected” or similar words are not limited to physical or mechanical connections, but can include electrical connections, whether direct or indirect. The terms “up”, “down”, “left”, “right”, and the like are only defined to indicate relative positional relationships. In the case where an absolute position of described objects changes, a relative position relationship may also change accordingly.

In order to make a person skilled in the art better understand the technical solutions of the present disclosure, a shift register, a gate driving circuit, a display panel and a display device provided by the present disclosure will be further described in detail below with reference to the accompanying drawings.

The terms “first”, “second,” or similar words used in the embodiments of the present disclosure do not indicate any order, quantity or importance, but are only used to distinguish different components. Similarly, the terms “include”, “comprise” or similar words indicate that elements or objects stated before them encompass the elements or objects and equivalents thereof listed after them, but do not exclude other elements or objects. The terms “coupling” or “connected” or similar words are not limited to physical or mechanical coupling, but can include electrical coupling, whether direct or indirect.

Transistors used in the embodiments of the present disclosure may be thin film transistors (TFTs), field effect transistors or other devices with same characteristics. Since a source and a drain of a transistor used are symmetrical, there is no difference between the source and the drain. In the embodiments of the present disclosure, in order to distinguish the source and the drain of the transistor, one of the source and the drain is referred to as a first electrode, the other is referred to as a second electrode, and a gate is referred to as a control electrode. In addition, the transistors may be divided into N-type transistors and P-type transistors according to characteristics of the transistors, and the N-type transistors are used as an example for description in the following embodiments. When using an N-type transistor, a first electrode is a source of the N-type transistor, a second electrode is a drain of the N-type transistor, and when a high level is inputted to a gate, the source and the drain are turned on. When using a P-type transistor, the reverse applies. It is conceivable that using the P-type transistor for implementation is readily apparent to a person skilled in the art without creative labor, and thus falls within the protection scope of the embodiments of the present disclosure.

Meanwhile, in the embodiments of the present disclosure, an “active level signal” refers to a signal that can control a transistor to be turned on after being input to a control electrode of the transistor, and an “inactive level signal” refers to a signal that can control the transistor to be turned off after being input to the control electrode of the transistor. For an N-type transistor, a high level signal is an active level signal, and a low level signal is an inactive level signal; and for a P-type transistor, a low level signal is an active level signal, and a high level signal is an inactive level signal.

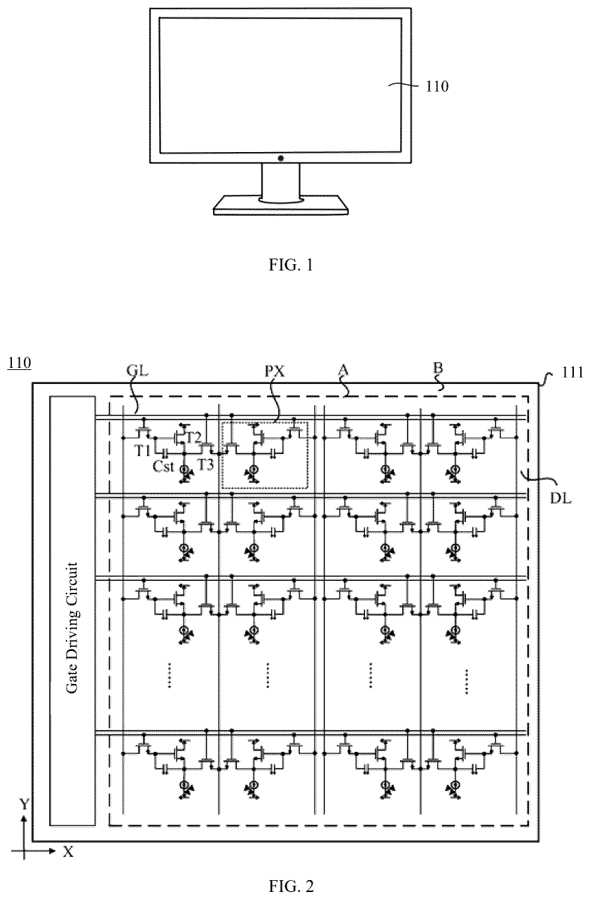

FIG. 1 exemplarily illustrates a front structure of a display device. As shown in FIG. 1, some embodiments of the present disclosure provide a display device. The display device may be any device that displays text or images whether moving (for example, videos) or stationary (for example, still images). More specifically, it is anticipated that the embodiments may be implemented in, or associated with, a variety of electronic devices. The variety of electronic devices are, for example (but not limit to), mobile phones, wireless devices, personal data assistants (PDAs), hand-held or portable computers, global positioning system (GPS) receivers/navigators, cameras, MP4 video players, camcorders, game consoles, watches, clocks, calculators, television monitors, flat panel displays, computer monitors, auto displays (for example, odometer displays), navigators, cockpit controllers and/or displays, camera view displays (for example, rear-view camera displays in vehicles), electronic photos, electronic billboards or signs, projectors, architectural structures, packaging and aesthetic structures (for example, displays for displaying an image of a piece of jewelry). In FIG. 1, the display device is illustrated as a television.

The display device includes a display panel. For example, the display device includes a housing and a display panel, where the display panel is connected to the housing. In practical applications, the display device can further include a circuit board, a display driver integrated circuit (IC) and other electronic components arranged inside the housing.

The display panel may be a liquid crystal display (LCD), or the display panel may also be an electroluminescent display panel or a photoluminescence display panel. In the case where the display panel is the electroluminescent display panel, the electroluminescent display panel may be an organic light-emitting diode (OLED) display panel or a quantum dot light emitting diode (QLED) display panel. In the case where the display panel is the photoluminescence display panel, the photoluminescence display device may be a quantum dot photoluminescence display panel. Taking the display panel as an organic light-emitting diode (OLED) display panel as an example for description in some embodiments of the present disclosure.

FIG. 2 exemplarily illustrates a structural diagram of a display panel. As shown in FIG. 2, the display panel includes a substrate, and a plurality of sub-pixels PX, a plurality of gate lines GL and a plurality of data lines DL arranged on a side of the substrate.

The substrate can be a rigid substrate or a flexible substrate, which can be selected and set according to actual needs.

For example, the substrate is the rigid substrate. For example, the rigid substrate can be a glass substrate, a polymethyl methacrylate (PMMA) substrate, or the like.

For example, the substrate may be the flexible substrate. For example, the flexible substrate can be a polyethylene terephthalate (PET) substrate, a polyethylene naphthalate two formic acid glycol ester (PEN) substrate or a polyimide (PI) substrate.

The display panel may have a display area A and a non-display area B electrically connected to the display area A. The non-display area B can be located on one side, two sides or three sides of the display area A, or the non-display area B can be arranged around the display area A. The plurality of sub-pixels PX, the plurality of gate lines GL and the plurality of data lines DL can be located in the display area A.

For example, the plurality of sub-pixels PX can be arranged in an array. For example, the plurality of sub-pixels PX are arranged in an array to form a plurality of sub-pixel rows and a plurality of sub-pixel columns. The plurality of sub-pixels PX in a sub-pixel row are arranged along a first direction X, and the plurality of sub-pixels PX in a sub-pixel column are arranged along a second direction Y.

The first direction X and the second direction Y intersect with each other. An included angle between the first direction X and the second direction Y can be selected and set according to actual needs. For example, the included angle between the first direction X and the second direction Y can be 85°, 88°, 90°, 92°, 95°, or the like.

Each of the plurality of sub-pixels PX can include a pixel driving circuit P1 and a light emitting device P2 electrically connected to the pixel driving circuit P1. When the display panel operates, the light emitting device P2 can emit light under the driving of the pixel driving circuit P1.

For example, a gate line GL can be electrically connected to the plurality of sub-pixels PX in the sub-pixel row, and a data line DL can be electrically connected to a plurality of pixel driving circuits P1 in the sub-pixel column.

The pixel driving circuit Pl includes various structures, which can be selected and set according to actual needs. For example, the structure of the pixel driving circuit P1 can include structures such as 3T1C, 6TIC, 7T1C, 6T2C or 7T2C. “T” represents transistors, a number before “T” represents a number of transistors, “C” represents storage capacitors, and a number before “C” represents a number of storage capacitors.

During the use of the display device, the stability of the transistor in the pixel driving circuit P1 and the light-emitting diode OLED may decrease (for example, a threshold voltage of a driving transistor drifts), which affects the display effect of the display device, and thus it is necessary to compensate the sub-pixel PX.

There are many manners to compensate the sub-pixel PX, which can be selected and set according to actual needs. For example, a pixel compensation circuit can be provided in the sub-pixel PX to perform internal compensation on the sub-pixel PX. For another example, the driving transistor or the light emitting device can be sensed by the transistor inside the sub-pixel PX, and sensed data can be transmitted to an external induction circuit to calculate a driving voltage value to be compensated using the external induction circuit and provide feedback, thereby realizing external compensation for the sub-pixel PX.

In the present disclosure, taking the use of external compensation (sensing the driving transistor) and the pixel driving circuit using a structure of “3T1C” as an example, a structure and an operating process of the sub-pixel PX are schematically illustrated.

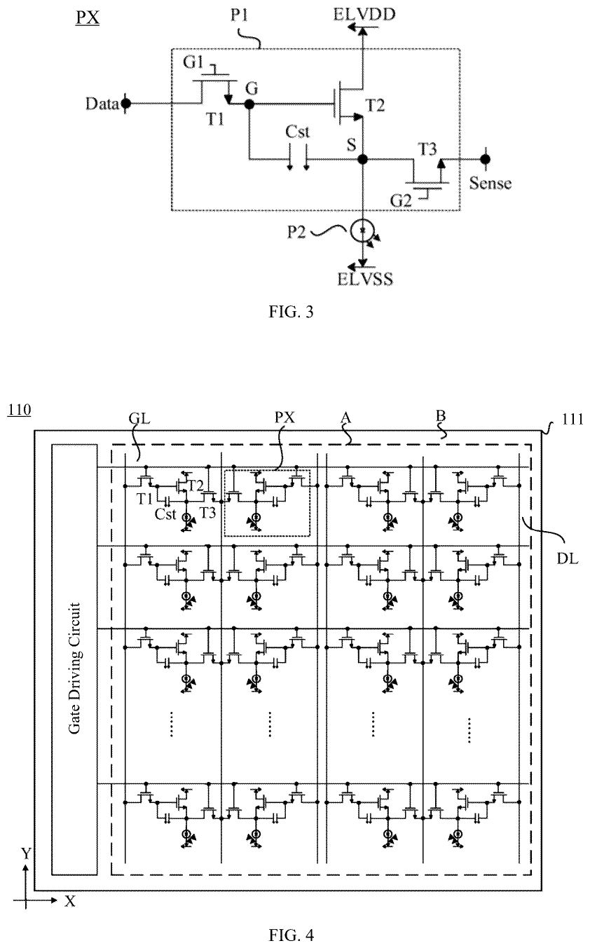

FIG. 3 exemplarily illustrates a circuit diagram of a pixel driving circuit. For example, as shown in FIG. 3, the pixel driving circuit P1 can include a switching transistor T1, a driving transistor T2, a sensing transistor T3 and a storage capacitor Cst.

A control electrode of the switching transistor T1 is electrically connected to a first gate signal terminal G1, a first electrode of the switching transistor T1 is electrically connected to a data signal terminal Data, and a second electrode of the switching transistor T1 is electrically connected to a node G. The switching transistor T1 is configured to transmit a data signal of the data signal terminal Data to the node G under the control of a first scanning signal of the first gate signal terminal G1.

Here, for example, the data signal includes a detection data signal and a display data signal. The detection data signal is used in a blanking period and the display data signal is used in a display period. With regard to the display period and the blanking period, reference can be made to following descriptions in some embodiments, which will not be repeated here.

A control electrode of the driving transistor T2 is electrically connected to the node G, a first electrode of the driving transistor T2 is electrically connected to a sixth voltage signal terminal ELVDD, and a second electrode of the driving transistor T2 is electrically connected to a node S. The driving transistor T2 is configured to be turned on under the control of a signal of the node G, and write a driving signal related to the node G and the sixth voltage signal terminal EL VDD at the node S.

A first terminal of the storage capacitor Cst is electrically connected to the node G, and a second terminal of the storage capacitor Cst is electrically connected to the node S. The switching transistor T1 charges the storage capacitor Cst while charging the node G.

An anode of the light emitting device P2 is electrically connected to the node S, and a cathode of the light emitting device P2 is electrically connected to a seventh voltage signal terminal ELVSS. The light emitting device P2 is configured to emit light under the driving of a driving signal.

A control electrode of the sensing transistor T3 is electrically connected to a second gate signal terminal G2, a first electrode of the sensing transistor T3 is electrically connected to the node S, and a second electrode of the sensing transistor T3 is electrically connected to a sensing signal terminal Sense. The sensing transistor T3 is configured to detect electrical characteristics of the driving transistor T2 to realize external compensation under the control of a second scanning signal of the second gate signal terminal G2. For example, the electrical characteristics include a threshold voltage and/or the carrier mobility of the driving transistor T2.

Here, the sensing signal terminal Sense can provide a reset signal or an acquisition sensing signal. The reset signal is used to reset the node S in the display period and the acquisition sensing signal is used to acquire the threshold voltage and/or the carrier mobility of the driving transistor T2 in the blanking period.

When the structure of the pixel driving circuit P1 uses the structure shown in FIG. 3, the plurality of pixel driving circuits P1 in a sub-pixel row can be electrically connected to two gate lines GL. For example, the plurality of gate lines include a first gate line and a second gate line. The first gate line is electrically connected to a plurality of first gate signal terminals G1 in a sub-pixel row, so that each of the plurality of first gate signal terminals G1 can receive a first scanning signal through the first gate line; and the second gate line is electrically connected to a plurality of second gate signal terminals G2 in a sub-pixel row, so that each of the plurality of second gate signal terminals G2 can receive a second scanning signal through the second gate line.

Of course, it is possible that the plurality of pixel driving circuits P1 in a sub-pixel row are electrically connected to a gate line GL. FIG. 4 exemplarily illustrates a structural diagram of another display panel. As shown in FIG. 4, the first gate signal terminal G1 and the second gate signal terminal G2 in a sub-pixel row are both electrically connected to the same gate line GL.

Referring to FIG. 2, a side of the substrate is further provided with a gate driving circuit, and the gate driving circuit is located on the same side of the substrate as the above sub-pixels PX, gate lines GL and data lines DL. The gate driving circuit includes a plurality of cascaded shift registers, each of the plurality of cascaded shift registers includes an output terminal, and the output terminal of the shift register can be electrically connected to the gate line GL. When the gate driving circuit operates, the plurality of cascaded shift registers output the first scanning signal and the second scanning signal to the pixel driving circuit P1 step by step through the output terminals.

It should be noted that in a display stage of one frame, the first scanning signal transmitted by the first gate signal terminal G1 and the second scanning signal transmitted by the second gate signal terminal G2 are both provided by the gate driving circuit. That is, each shift register in the gate driving circuit can be electrically connected to the first gate signal terminal G1 through the first gate line to transmit the first scanning signal to the first gate signal terminal G1 through the first gate line and electrically connected to the second gate signal terminal G2 through the second gate line to transmit the second scanning signal to the second scanning signal terminal G2 through the second gate line.

FIG. 4 exemplarily illustrates a structural diagram of another display panel. As shown in FIG. 4, the first gate signal terminal G1 and the second gate signal terminal G2 of the plurality of pixel driving circuits P1 in a sub-pixel row can also be electrically connected to the same gate line GL. In this case, the first scanning signal and the second scanning signal are the same. Each shift register in the gate driving circuit can be electrically connected to the first gate signal terminal G1 and the second gate signal terminal G2 through the gate line GL corresponding to the shift register, and a scanning signal can be transmitted to the first gate signal terminal G1 and the second gate signal terminal G2 through the gate line GL.

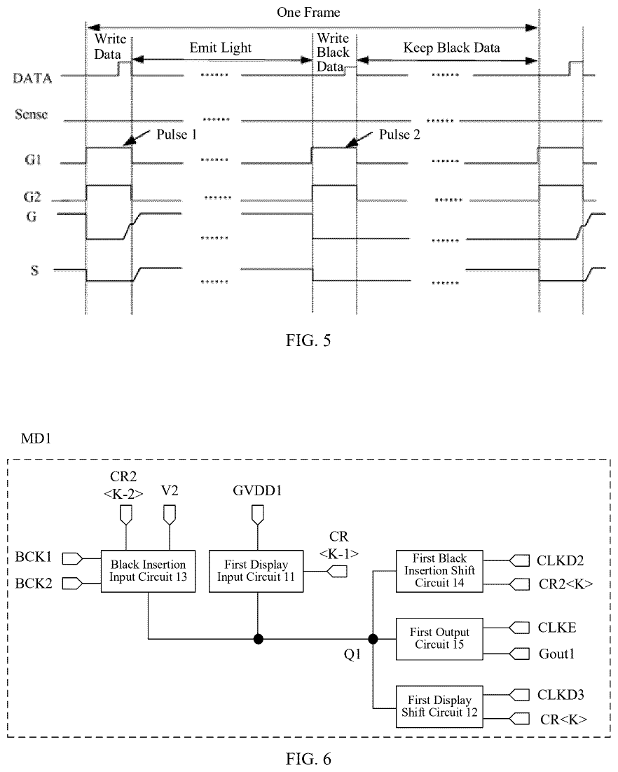

In the related art, a dynamic image smear may occur during the operating process of the sub-pixel PX, that is, when the display device switches from one frame of image to another frame of image, a user may feel the smear of the previous frame of image. In order to improve the problem of image smear, a process of writing black data and a process of keeping black data can be set in a light emission process of sub-pixel PX. FIG. 5 exemplarily illustrates a signal timing diagram of a pixel driving circuit shown in FIG. 3. As shown in FIG. 5, the process of writing black data and the process of keeping black data are sequentially added in the original light emission process, that is, a black insertion process is set for the screen, which reduces the light emission time duration and enhances the moving picture response time (MPRT), and the larger the MPRT is, the weaker the smear is.

Controlling the pixel driving circuit P1 to write data and emit light is called display driving, and controlling the pixel driving circuit P1 to write black data and keep black data is called black insertion driving. The gate driving circuit can simultaneously have a display driving function and a black insertion driving function, that is, the shift register of each stage in the gate driving circuit can be used for both display driving and black insertion driving. As can be seen from FIG. 5, a time of display driving and a time of black insertion driving are not synchronous, and thus the circuit structure for realizing display driving in the gate driving circuit can have a different cascade relationship with the circuit structure for realizing black insertion driving.

The operating process of the gate driving circuit can include a display driving stage and a black insertion driving stage, which are alternately performed. In the display driving stage, shift registers of certain stages in the gate driving circuit sequentially output display driving signals (for example, a pulse 1 in FIG. 5) through the output terminals; and in the black insertion driving stage, the output terminals of the shift registers of certain stages in the gate driving circuit output black insertion driving signals (for example, a pulse 2 in FIG. 5) for black insertion driving.

FIG. 6 exemplarily illustrates a circuit block diagram of a shift register. As shown in FIG. 6, the shift register includes a first scanning unit MD1. The first scanning unit MD1 includes a first display input circuit 11, a first display shift circuit 12, a black insertion input circuit 13, a first black insertion shift circuit 14 and a first output circuit 15.

The first display input circuit 11 is electrically connected to a first voltage terminal GVDD1, a first display input terminal CR<K−1> and a first pull-up node Q1. The first output circuit 15 is electrically connected to the first pull-up node Q1, a first signal terminal CLKE1 and a first output terminal Gout1. The first display shift circuit 12 is electrically connected to the first pull-up node Q1, a first shift signal terminal CLKD3 and a first shift output terminal CR<K>.

In the display driving stage, the first display input circuit 11 is configured to write a signal of the first voltage terminal GVDD1 into the first pull-up node Q1 under the control of a signal of the first display input terminal CR<K−1>, and the first output circuit 15 is configured to write a signal of the first signal terminal into the first output terminal Gout1 under the control of a signal of the first pull-up node Q1. The first display shift circuit 12 is configured to write a signal of the first shift signal terminal CLKD3 into the first shift output terminal CR<K> under the control of the signal of the first pull-up node Q1.

The first voltage terminal GVDD1 can be supplied with a constant level signal. For example, the first voltage terminal GVDD1 is supplied with a constant high level signal. For example, the display panel includes a first voltage line into which a constant high level signal is passed, and the first voltage line is electrically connected to the first voltage terminal GVDD1.

The first pull-up node Q1 does not represent an actual component, but represents a junction point of related electrical connections in the circuit diagrams, that is, the first pull-up node Q1 is a node equivalent to the junction point of the related electrical connections in the circuit diagrams. Similarly, a second pull-up node Q2, a first pull-down node QB1, a second pull-down node QB2, the node G, the node S, a first node P, and a second node M in the embodiments of the present disclosure are all nodes equivalent to the junction points of the related electrical connections in the circuit diagrams.

The first display input terminal CR<K−1> can be electrically connected to a start signal line STV to receive a start signal in the start signal line STV. For example, when the shift register is a first shift register in the gate driving circuit, the first display input terminal CR<K−1> in the shift register is electrically connected to the start signal line STV. The first display input terminal CR<K−1> can also be electrically connected to a shift register of a previous stage to receive a first shift signal output by the shift register of the previous stage. For example, the shift register is a nth shift register (n>1), and the first display input terminal CR<K−1> of the nth shift register is electrically connected to a (n−1)th shift register.

The first output terminal Gout1 can be electrically connected to the gate line GL to provide a scanning signal to the first gate signal terminal G1 and/or the second gate signal terminal G2 through the gate line GL.

The first signal terminal can be electrically connected to a clock signal line. For example, the gate driving circuit includes a plurality of display clock signal lines CE, and the first signal terminal is electrically connected to the plurality of display clock signal lines CE.

The first shift signal terminal CLKD3 can be electrically connected to the clock signal line. For example, the gate driving circuit includes a plurality of black insertion clock signal lines CD, and the first shift signal terminal CLKD3 is electrically connected to the plurality of black insertion clock signal lines CD.

For example, when the first display input terminal CR<K−1> receives a high level signal output by the shift register of the previous stage or the start signal line STV, a path between the first voltage terminal GVDD1 and the first pull-up node Q1 is conducted, and the high level signal of the first voltage terminal GVDD1 is written into the first pull-up node Q1, so that the signal of the first pull-up node Q1 is the high level signal. Under the control of the high level signal of the first pull-up node Q1, the first output circuit 15 conducts the path between the first signal terminal and the first output terminal Gout1, and the high level signal of the first signal terminal is written into the first output terminal Gout1, that is, the first output terminal Gout1 of the shift register provides the high level signal to the first gate signal terminal G1 and the second gate signal terminal G2 through the gate line GL, so that the pixel driving circuit P1 writes the image data signal. Under the control of the high level signal of the first pull-up node Q1, the first display shift circuit 12 conducts a path between the first shift signal terminal CLKD3 and the first shift output terminal CR<K>, and a high level signal of the first shift signal terminal CLKD3 is written into the first shift output terminal CR<K>.

That is, the first display input circuit 11, the first output circuit 15 and the first display shift circuit 12 constitute a display driving module to realize display driving. For example, the gate driving circuit can include a plurality of display driving modules, and the first shift output terminal CR<K>of the previous display driving module is electrically connected to the first display input terminal CR<K−1> of the next display driving module to realize the cascade of the plurality of display driving modules.

The black insertion input circuit 13 is electrically connected to a first black insertion input terminal CR2<K−2>, a first control terminal BCK1, a second voltage terminal V2, a second control terminal BCK2 and the first pull-up node Q1. The first black insertion shift circuit 14 is electrically connected to the first pull-up node Q1, a second shift signal terminal CLKD2 and a second shift output terminal CR2<K>.

In the black insertion driving stage, the black insertion input circuit 13 is configured to write a signal of the second voltage terminal V2 into the first pull-up node Q1 under the control of signals of the first black insertion input terminal CR2<K−2> and the first control terminal BCK1. The first output circuit 15 is further configured to write the signal of the first signal terminal into the first output terminal Gout1 under the control of the signal of the first pull-up node Q1. The first black insertion shift circuit 14 is configured to write a signal of the second signal terminal into the second shift output terminal CR2<K> under the control of the signal of the first pull-up node Q1.

The first control terminal BCK1 and the second control terminal BCK2 can be electrically connected to the clock signal line. For example, the gate driving circuit includes a plurality of control signal lines BC, and the first control terminal BCK1 and the second control terminal BCK2 can be electrically connected to different control signal lines BC.

The second voltage terminal V2 and the second control terminal BCK2 can be supplied with the same signal, for example, the second voltage terminal V2 is electrically connected to the second control terminal BCK2. The second voltage terminal V2 can also be supplied with a constant level signal. For example, the display panel includes a fourth voltage line GVDD4, where the fourth voltage line GVDD4 is supplied with a constant high level signal, and the second voltage terminal V2 is electrically connected to the fourth voltage line GVDD4.

For example, the first black insertion input terminal CR2<K−2>, the first control terminal BCK1 and the second control terminal BCK2 all receive high level signals, so that the path between the second voltage terminal V2 and the first pull-up node Q1 is conducted, and the high level signal of the second voltage terminal V2 is written into the first pull-up node Q1. The first output circuit 15 conducts the path between the first signal terminal and the first output terminal Gout1 under the control of the high level signal of the first pull-up node Q1, and the high level signal of the first signal terminal is written into the first output terminal Gout1, that is, the first output terminal Gout1 of the shift register provides the high level signal to the first gate signal terminal G1 and the second gate signal terminal G2 through the gate line GL, so that the pixel driving circuit P1 writes the black data signal. Under the control of the high level signal of the first pull-up node Q1, the first black insertion shift circuit 14 conducts the path between the second shift signal terminal CLKD2 and the second shift output terminal CR2<K>, and the high level signal of the second shift signal terminal CLKD2 is written into the second shift output terminal CR2<K>.

That is, the black insertion input circuit 13, the first output circuit 15 and the first black insertion shift circuit 14 constitute a black insertion driving module to realize black insertion driving. The gate driving circuit can include a plurality of black insertion driving modules, and the previous black insertion driving module and the next black insertion driving module can be cascaded through the first black insertion shift circuit 14.

In the shift register of the embodiments of the present disclosure, the first black insertion input circuit 13, the first black insertion shift circuit 14, the first display input circuit 11, the first display shift circuit 12 and the first output circuit 15 are simultaneously provided, where the first output circuit 15 is electrically connected to a pixel driving circuit P1 to control the pixel driving circuit P1 to write an image data signal and a black data signal; the first black insertion input circuit 13, the first output circuit 15 and the first black insertion shift circuit 14 constitute a black insertion driving module to realize black insertion driving, and the first display input circuit 11, the first output circuit 15 and the first display shift circuit 12 constitute a display driving module to realize display driving; the first black insertion shift circuit 14 may be used to realize a cascade of different black insertion driving modules, and the first display shift circuit 12 may be used to realize a cascade of different display driving modules, that is, the first black insertion shift circuit 14 is provided separately to realize the cascade of different black insertion driving modules. Compared with the related art in which the cascade of black insertion driving modules is realized by multiplexing the display shift circuit and/or the display output circuit, the number of shift registers spanned by the first black insertion shift circuit 14 in the embodiments of the present disclosure when cascaded is less, and thus the wiring difficulty is lower.

The first scanning unit MD1 can include a plurality of first output circuits 15. The plurality of first output circuits 15 are electrically connected to different gate lines GL, so that the first scanning unit MD1 can drive multiple rows of sub-pixels PX at the same time, thereby reducing the number of the first scanning units MD1. The more the number of first output circuits 15 included in the first scanning unit MD1, the less the number of first scanning units MD1 is required, but the more the number of display clock signal lines electrically connected to the first output circuits 15 is required. Therefore, the first scanning unit MD1 can include four first output circuits 15, and the number of display clock signal lines will not increase too much on the premise of reducing the number of the first scanning units MD1.

For example, the display clock signal lines include a first display clock signal line CE1, a second display clock signal line CE2, a third display clock signal line CE3 and a fourth display clock signal line CE4, and the four display clock signal lines are respectively electrically connected to four first output circuits 15. The first output circuit 15 electrically connected to the first display clock signal line CE1 is electrically connected to the Nth row sub-pixel PX, the first output circuit 15 electrically connected to the second display clock signal line CE2 is electrically connected to the (N+1)th row sub-pixel PX, the first output circuit 15 electrically connected to the third display clock signal line CE3 is electrically connected to the (N+2)th row sub-pixel PX, and the first output circuit 15 electrically connected to the fourth display clock signal line CE4 is electrically connected to the (N+3)th row sub-pixel PX.

Of course, the embodiments of the present disclosure do not limit the number of the first output circuits 15 in the first scanning unit MD1, and the number of the first output circuits 15 may be one, two, three, five, and the like.

The shift register can only include the first scanning unit MD1, and at this time, a plurality of shift registers in the gate driving circuit are cascaded, that is, a plurality of first scanning units MD1 are cascaded. For example, a plurality of shift registers can include a first shift register and a second shift register which are cascaded. The first shift output terminal CR<K> of the first shift register is electrically connected to the first display input terminal CR<K−1> of the second shift register, and the second shift output terminal CR2<K> of the first shift register is electrically connected to the first black insertion input terminal CR2<K−2> of the second shift register.

For example, the gate driving circuit includes a first control signal line BC1, a second control signal line BC2, a third control signal line BC3 and a fourth control signal line BC4, and further includes a second black insertion clock signal line CD2, a third black insertion clock signal line CD3, a sixth black insertion clock signal line CD6 and a seventh black insertion clock signal line CD7, and further includes a first display clock signal line CE1, a second display clock signal line CE2, a third display clock signal line CE3, a fourth display clock signal line CE4, a fifth display clock signal line CE5, a sixth display clock signal line CE6, a seventh display clock signal line CE7 and an eighth display clock signal line CE8. The first control signal line BC1 is electrically connected to the first control terminal BCK1 of the first shift register, the second control signal line BC2 is electrically connected to the second control terminal BCK2 of the first shift register and the second voltage terminal V2, the third control signal line BC3 is electrically connected to the first control terminal BCK1 of the second shift register, and the fourth control signal line BC4 is electrically connected to the second control terminal BCK2 of the second shift register and the second voltage terminal V2. The second black insertion clock signal line CD2 is electrically connected to the second shift signal terminal CLKD2 of the first shift register, and the third black insertion clock signal line CD3 is electrically connected to the first shift signal terminal CLKD3 of the first shift register. The seventh black insertion clock signal line CD7 is electrically connected to the first shift signal terminal CLKD3 of the second shift register, and the sixth black insertion clock signal line CD6 is electrically connected to the second shift signal terminal CLKD2 of the second shift register. The four first output circuits 15 of the first shift register are respectively electrically connected to the first display clock signal line CE1, the second display clock signal line CE2, the third display clock signal line CE3 and the fourth display clock signal line CE4, and the four first output circuits 15 of the second shift register are respectively electrically connected to the fifth display clock signal line CE5, the sixth display clock signal line CE6, the seventh display clock signal line CE7 and the eighth display clock signal line CE8.

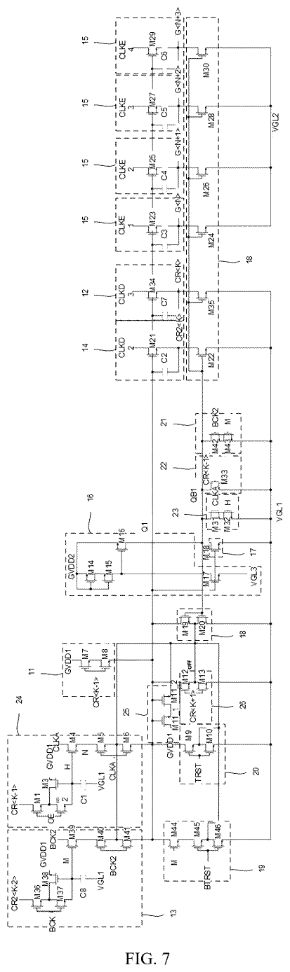

FIG. 7 exemplarily illustrates a circuit diagram of a first scanning unit. As shown in FIG. 7, the first scanning unit MD1 can further include a first pull-down circuit 17, a first pull-down control circuit 16, a first noise reduction circuit 18, a first reset circuit 20, a second reset circuit 26, a third reset circuit 22, a fourth reset circuit 23 and a first blanking circuit 24.

The first pull-down control circuit 16 is electrically connected to a third voltage terminal and the first pull-down node QB1, and the first pull-down control circuit 16 is configured to write a signal of the third voltage terminal into the first pull-down node QB1.

For example, the first pull-down control circuit 16 includes a fourteenth transistor M14, a fifteenth transistor M15, a sixteenth transistor M16 and a seventeenth transistor M17. The fourteenth transistor M14 and the fifteenth transistor M15 are connected in series, a control electrode of the fourteenth transistor M14 and a control electrode of the fifteenth transistor M15 are both electrically connected to the second voltage line GVDD2; a second electrode of the fifteenth transistor M15 is electrically connected to a control electrode of the sixteenth transistor M16, a first electrode of the sixteenth transistor M16 is electrically connected to the second voltage line GVDD2, and a second electrode of the sixteenth transistor M16 is electrically connected to the first pull-down node QB1; a control electrode of the seventeenth transistor M17 is electrically connected to the first pull-up node Q1, a second electrode of the seventeenth transistor M17 is electrically connected to the second electrode of the fifteenth transistor M15, and a first electrode of the seventeenth transistor M17 is electrically connected to the first pull-down node QB1.

The first pull-down circuit 17 is electrically connected to the first pull-up node Q1, a first reset voltage terminal VGL1 and the first pull-down node QB1, and is configured to write a signal of the first reset voltage terminal VGL1 into the first pull-down node QB1 under the control of the signal of the first pull-up node Q1.

For example, the first pull-down circuit 17 includes an eighteenth transistor M18, where a control electrode of the eighteenth transistor M18 is electrically connected to the first pull-up node Q1, a first electrode of the eighteenth transistor M18 is electrically connected to the first reset voltage terminal VGL1, and a second electrode of the eighteenth transistor M18 is electrically connected to the first pull-down node QB1.

The first noise reduction circuit 18 is electrically connected to the first pull-down node QB1, the first pull-up node Q1, the first reset voltage terminal VGL1, the first shift output terminal CR<K> and the second shift output terminal CR2<K>, and is configured to write the signal of the first reset voltage terminal VGL1 into the first pull-up node Q1, the first shift output terminal CR<K> and the second shift output terminal CR2<K> under the control of the signal of the first pull-down node QB1.

For example, the first noise reduction circuit 18 includes a nineteenth transistor M19, a twentieth transistor M20, a twenty-second transistor M22, a twenty-fourth transistor M24, a twenty-sixth transistor M26, a twenty-eighth transistor M28, a thirtieth transistor M30 and a thirty-fifth transistor M35. The nineteenth transistor M19 and the twentieth transistor M20 are connected in series, and a control electrode of the nineteenth transistor M19 and a control electrode of the twentieth transistor M20 are electrically connected to the first pull-down node QB1, a first electrode of the twentieth transistor M20 is electrically connected to the first reset voltage terminal VGL1, and a second electrode of the nineteenth transistor M19 is electrically connected to the first pull-up node Q1. A control electrode of the twenty-second transistor M22, a control electrode of the twenty-fourth transistor M24, a control electrode of the twenty-sixth transistor M26, a control electrode of the twenty-eighth transistor M28, a control electrode of the thirtieth transistor M30 and a control electrode of the thirty-fifth transistor M35 are electrically connected to the first pull-down node QB1, a first electrode of the twenty-second transistor M22 and a first electrode of the thirty-fifth transistor M35 are electrically connected to the first reset voltage terminal VGL1, a second electrode of the twenty-second transistor M22 is electrically connected to the second shift output terminal CR2<K>, and a second electrode of the thirty-fifth transistor M35 is electrically connected to the first shift output terminal CR<K>. A second electrode of the twenty-fourth transistor M24, a second electrode of the twenty-sixth transistor M26, a second electrode of the twenty-eighth transistor M28 and a second electrode of the thirtieth transistor M30 are electrically connected to the first output terminal Gout1, and a first electrode is electrically connected to the second reset voltage terminal VGL2. The second reset voltage terminal VGL2 can be connected to a constant low level signal.

The first reset circuit 20 is electrically connected to a reset signal terminal TRST, the first pull-up node Q1 and the first reset voltage terminal VGL1, and is configured to write the signal of the first reset voltage terminal VGL1 into the first pull-up node Q1 under the control of a signal of the reset signal terminal TRST.

For example, the first reset circuit 20 includes a ninth transistor M9 and a tenth transistor M10, a control electrode of the ninth transistor M9 and a control electrode of the tenth transistor M10 are electrically connected to a reset control terminal, a first electrode of the tenth transistor M10 is electrically connected to the first reset voltage terminal VGL1, and a second electrode of the ninth transistor M9 is electrically connected to the first pull-up node Q1.

The second reset circuit 26 is electrically connected to a reset input terminal, the first pull-up node Q1 and the first reset voltage terminal VGL1, and is configured to write the signal of the first reset voltage terminal VGL1 into the first pull-up node Q1 under the control of a signal of the reset input terminal. The reset input terminal can be electrically connected to a first shift output terminal CR<K+1> of a scanning unit of a next stage.

For example, the second reset circuit 26 includes a twelfth transistor M12 and a thirteenth transistor M13. The twelfth transistor M12 and the thirteenth transistor M13 are connected in series, a control electrode of the twelfth transistor M12 and a control electrode of the thirteenth transistor M13 are electrically connected to the reset input terminal, a second electrode of the twelfth transistor M12 is electrically connected to the first pull-up node Q1, and a first electrode of the thirteenth transistor M13 is electrically connected to the first reset voltage terminal VGL1.

The third reset circuit 22 is electrically connected to the first pull-down node QB1, the first reset voltage terminal VGL1 and the first display input terminal CR<K−1>, and is configured to write the signal of the first reset voltage terminal VGL1 into the first pull-down node QB1 under the control of the signal of the first display input terminal CR<K−1>.

For example, the third reset circuit 22 includes a thirty-third transistor M33, where a control electrode of the thirty-third transistor M33 is electrically connected to the first display input terminal CR<K−1>, a first electrode of the thirty-third transistor M33 is electrically connected to the first reset voltage terminal VGL1, and a second electrode of the thirty-third transistor M33 is electrically connected to the first pull-down node QB1.

The first blanking circuit 24 is electrically connected to a fifth control terminal OE, the first display input terminal CR<K−1>, a fourth voltage terminal CLKA and the first pull-up node Q1, and is configured to write a signal of the fourth voltage terminal CLKA into the first pull-up node Q1 under the control of signals of the fifth control terminal and the first display input terminal CR<K−1>.

For example, when the signals of the first display input terminal CR<K−1>, the fifth control terminal OE and the fourth voltage terminal CLKA are all high level signals, the high level signal of the fourth voltage terminal CLKA is written into the first pull-up node Q1, and the first output circuit 15 writes the high level signal of the first signal terminal into the first output terminal Gout1 under the control of the high level signal of the first pull-up node Q1, and the first output terminal Gout1 provides a high level signal to the second gate signal terminal G1 through the gate line GL to reset the node S or drive the sub-pixel PX for black screen display. In this way, by cooperating with the electric signal on the sensing signal line on the display substrate, the effect of eliminating smear in the display screen is realized.

For example, the first blanking circuit 24 includes a first capacitor C1, a first transistor M1, a second transistor M2, a third transistor M3, a fourth transistor M4 and a fifth transistor M5. The first transistor M1 and the second transistor M2 are connected in series, a control electrode of the first transistor M1 and a control electrode of the second transistor M2 are electrically connected to the fifth control terminal OE, a second electrode of the first transistor MI is connected to the first display input terminal CR<K−1>, a first electrode of the second transistor M2 is electrically connected to a node H, a second electrode of the third transistor M3 is connected between the first transistor M1 and the second transistor M2, a first electrode of the third transistor M3 is connected to a first voltage line point, one plate of the first capacitor C1 is electrically connected to the node H, the other plate is electrically connected to the first reset voltage terminal VGL1, a control electrode of the fourth transistor M4 is electrically connected to the node H, a second electrode of the fourth transistor M4 is electrically connected to the fourth voltage terminal CLKA, a first electrode of the fourth transistor M4 is electrically connected to a node N, the fifth transistor M5 and the sixth transistor M6 are connected in series, a control electrode of the fifth transistor M5 and a control electrode of the sixth transistor M6 are electrically connected to the fourth voltage terminal CLKA, a second electrode of the fifth transistor M5 is electrically connected to the node N, and a first electrode of the sixth transistor M6 is electrically connected to the first pull-up node Q1.

The fourth reset circuit 23 is electrically connected to the first pull-down node QB1, the first reset voltage terminal VGL1, the fourth voltage terminal CLKA and the node H, and is configured to write the signal of the first reset voltage terminal VGL1 into the first pull-down node QB1 under the control of signals of the node H and the fourth voltage terminal CLKA.

For example, the fourth reset circuit 23 includes a thirty-first transistor M31 and a thirty-second transistor M32. A control electrode of the thirty-first transistor M31 is electrically connected to the fourth voltage terminal CLKA, a control electrode of the thirty-second transistor M32 is electrically connected to the node H, a second electrode of the thirty-first transistor M31 is electrically connected to the first pull-down node QB1, and a first electrode of the thirty-second transistor M32 is electrically connected to the first reset voltage terminal VGL1.

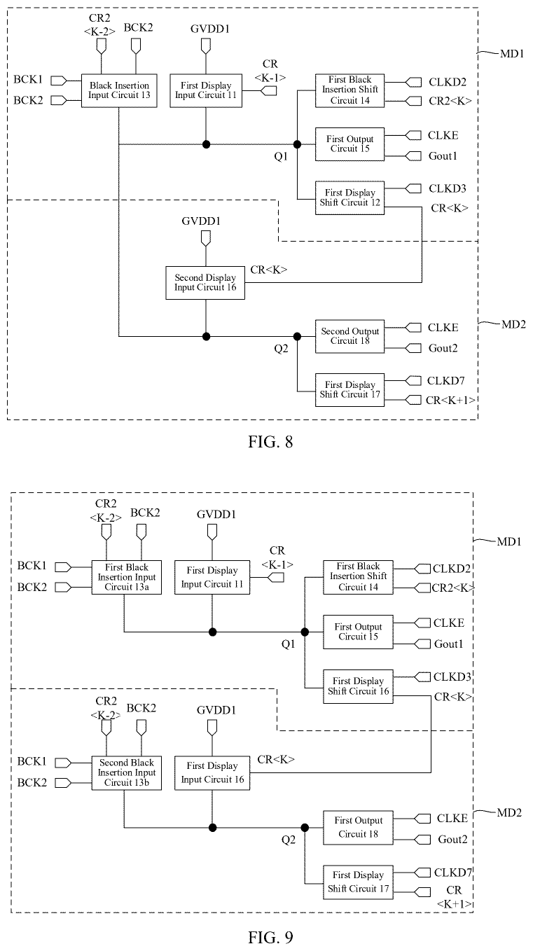

FIG. 8 exemplarily illustrates a structural block diagram of another shift register. As shown in FIG. 8, the shift register can further include a second scanning unit MD2, where the second scanning unit MD2 includes a second display input circuit 16, a second display shift circuit 17 and a second output circuit 18.

The second display input circuit 16 is electrically connected to the first shift output terminal CR<K>, the first voltage terminal GVDD1 and the second pull-up node Q2; the second display shift circuit 17 is electrically connected to the second pull-up node Q2, a third shift signal terminal CLKD7 and the third shift output terminal CR<K+1>; and the second output circuit 18 is electrically connected to the second pull-up node Q2, the second signal terminal and a second output terminal Gout2.

In the display driving stage, the second display input circuit 16 is configured to write the signal of the first voltage terminal GVDD1 into the second pull-up node Q2 under the control of the signal of the first shift output terminal CR<K>. The second display shift circuit 17 is configured to write a signal of the third shift signal terminal CLKD7 into the third shift output terminal CR<K+1> under the control of the signal of the second pull-up node Q2. The second output circuit 18 is configured to write the signal of the second signal terminal into the second output terminal Gout2 under the control of the signal of the second pull-up node Q2.

The third shift signal terminal CLKD7 can be electrically connected to the clock signal line. For example, the gate drive circuit includes a plurality of black insertion clock signal lines CD, and the third shift signal terminal CLKD7 is electrically connected to the plurality of black insertion clock signal lines CD.

The third shift output terminal CR<K+1> is electrically connected to the first display input terminal CR<K−1> of the shift register of the next stage.

For example, when the second display input terminal receives the high level signal output by the first shift output terminal CR<K>, a path between the first voltage terminal GVDD1 and the second pull-up node Q2 is conducted, and the high level signal of the first voltage terminal GVDD1 is written into the second pull-up node Q2, so that the signal of the second pull-up node Q2 is a high level signal. Under the control of the high level signal of the second pull-up node Q2, the second output circuit 18 conducts the path between the second signal terminal and the second output terminal Gout2, and the high level signal of the second signal terminal is written into the second output terminal Gout2, that is, the second output terminal Gout2 of the shift register provides the high level signal to the first gate signal terminal G1 and the second gate signal terminal G2 through the gate line GL, so that the pixel driving circuit P1 writes the image data signal. The second display shift circuit 17 conducts the path between the second shift signal terminal CLKD2 and the second shift output terminal CR2<K> under the control of the high level signal of the second pull-up node Q2, and the high level signal of the second shift signal terminal CLKD2 is written into the second shift output terminal CR2<K>.

The second scanning unit MD2 can further include a second pull-down circuit, a second pull-down control circuit, a second noise reduction circuit, a first reset circuit, a second reset circuit, a third reset circuit, a fourth reset circuit, a fifth reset circuit and a second blanking circuit. The circuit structures and connection relationships of the second pull-down circuit, the second pull-down control circuit, the second noise reduction circuit, the first reset circuit, the second reset circuit, the third reset circuit, the fourth reset circuit, the fifth reset circuit and the second blanking circuit can refer to the first scanning unit MD1, and will not be described here. That is, the first scanning unit MD1 and the second scanning unit MD2 may have the same or similar structures except the black insertion input circuit 13 and the first black insertion shift circuit 14. In the following, only the structures of the first scanning unit MD1 and the second scanning unit MD2 except the black insertion input circuit 13 and the first black insertion shift circuit 14 are the same as an example.

The black insertion input circuit 13 is further electrically connected to the second pull-up node Q2, and is further configured to write a signal at the second pull-up node Q2. The sub-pixel PX electrically connected to the first scanning unit MD1 and the second scanning unit MD2 is controlled by the black insertion input circuit 13 to realize black insertion.

FIG. 9 exemplarily illustrates a structural block diagram of another shift register. As shown in FIG. 9, the black insertion input circuit 13 can include a first black insertion input circuit 13a and a second black insertion input circuit 13b. The first black insertion input circuit 13a is electrically connected to the first pull-up node Q1, and is configured to write a signal at a first node. The second black insertion input circuit 13b is electrically connected to the second pull-up node Q2, and is configured to write a signal at the second pull-up node Q2. That is, the sub-pixel PX electrically connected to the first scanning unit MD1 is driven by the first black insertion input circuit 13a to realize black insertion, and the sub-pixel PX electrically connected to the second scanning unit MD2 is driven by the second black insertion input circuit 13b to realize black insertion.

At the same time, the signal written by the first black insertion input circuit 13a at the first pull-up node Q1 and the signal written by the second black insertion input circuit 13b at the second pull-up node Q2 can be the same. The same signal means that the signal written by the first plug-in input circuit 13a at the first pull-up node Q1 can drive the first output circuit 15 to make the first signal terminal and the first output terminal Gout1 conductive, and the signal written by the second plug-in input circuit 13b at the second pull-up node Q2 can drive the second output circuit 18 to make the second signal terminal and the second output terminal Gout2 conductive, but level values of the two signals are not necessarily exactly the same.

When the signal written by the first pull-up node Q1 and the signal written by the second pull-up node Q2 can be the same, the sub-pixel PX electrically connected to the first black insertion input circuit 13a and the sub-pixel PX electrically connected to the second black insertion input circuit 13b can be simultaneously driven to realize black insertion, thereby reducing the black insertion time.

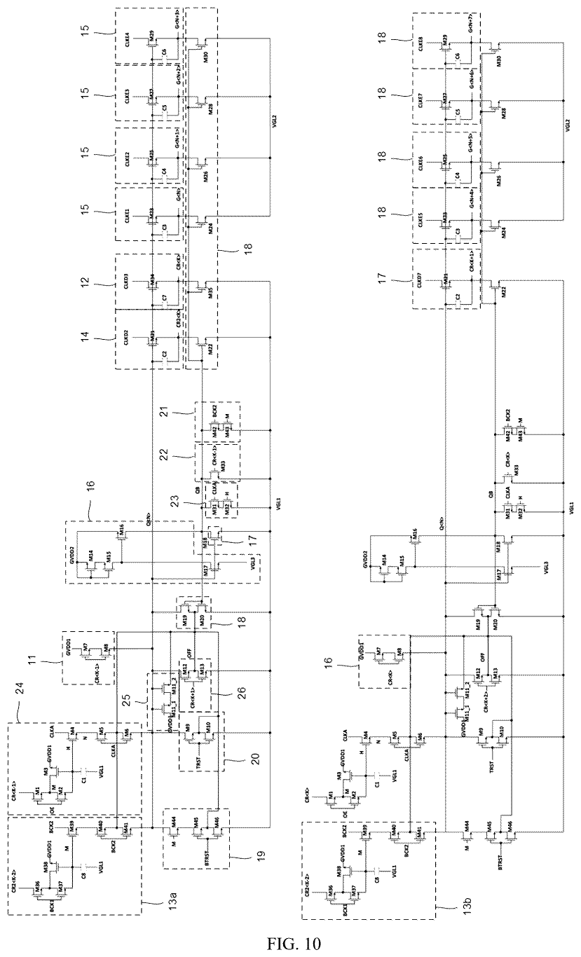

FIG. 10 exemplarily illustrates a circuit diagram of a shift register. As shown in FIG. 9 and FIG. 10,

The first black insertion input circuit 13a can be electrically connected to the first black insertion input terminal CR2<K−2>, the first control terminal BCK1, the second control terminal BCK2, the second voltage terminal V2 and the first pull-up node Q1, and is configured to write the signal of the second voltage terminal V2 into the first pull-up node Q1 under the control of signals of the first black insertion input terminal CR2<K−2>, the first control terminal BCK1 and the second control terminal BCK2.

The second black insertion input circuit 13b can also be electrically connected to the first black insertion input terminal CR2<K−2>, the first control terminal BCK1, the second control terminal BCK2, the second voltage terminal V2 and the second pull-up node Q2, and is configured to write the signal of the second voltage terminal V2 into the second pull-up node Q2 under the control of signals of the first black insertion input terminal CR2<K−2>, the first control terminal BCK1 and the second control terminal BCK2.

Since the first black insertion input circuit 13a and the second black insertion input circuit 13b are both electrically connected to the first black insertion input terminal, the first control terminal BCK1, the second control terminal BCK2 and the second voltage terminal V2, the signal written by the first black insertion input circuit 13a at the first pull-up node Q1 is the same as the signal that can be written by the second black insertion input circuit 13b at the second pull-up node Q2, and the number of signal lines electrically connected to the black insertion input circuit 13 is reduced.

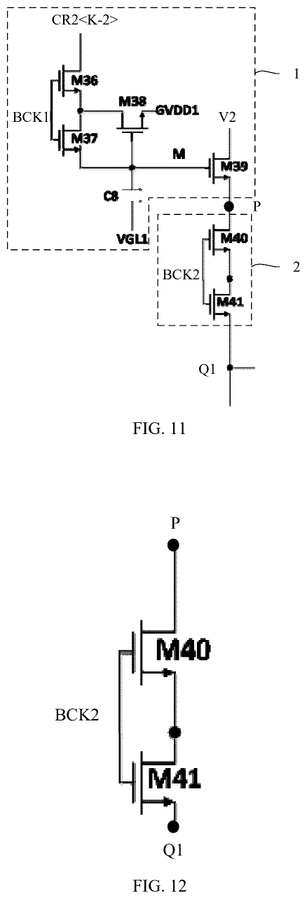

FIG. 11 exemplarily illustrates a circuit diagram of a first black insertion input circuit. As shown in FIG. 11, the first black insertion input circuit 13a includes a first sub-circuit 1 and a second sub-circuit 2.

The first sub-circuit 1 is electrically connected to the first black insertion input terminal CR2<K−2>, the first control terminal BCK1, the second voltage terminal V2 and the first node, and is configured to write the signal of the second voltage terminal V2 into the first node P under the control of the signals of the first black insertion input terminal CR2<K−2> and the first control terminal BCK1.

The second sub-circuit 2 is electrically connected to the second control terminal BCK2, the first node P and the first pull-up node Q1, and is configured to write the signal of the first node P into the first pull-up node Q1 under the control of the signal of the second control terminal BCK2.

For example, the first sub-circuit 1 includes a thirty-sixth transistor M36, a thirty-seventh transistor M37, a thirty-eighth transistor M38, an eighth capacitor C8 and a thirty-ninth transistor M39. The thirty-sixth transistor M36 and the thirty-seventh transistor M37 are connected in series, a gate of the thirty-sixth transistor M36 and a gate of the thirty-seventh transistor M37 are electrically connected to the first control terminal BCK1, a second electrode of the thirty-sixth transistor M36 is electrically connected to the first black insertion input terminal CR2<K−2>, and a first electrode of the thirty-seventh transistor M37 is electrically connected to the second node M; a second electrode of the thirty-eighth transistor M38 is connected between the thirty-sixth transistor M36 and the thirty-seventh transistor M37, and a first electrode of the thirty-eighth transistor M38 is electrically connected to the first voltage line GVDD1; one plate of the eighth capacitor C8 is electrically connected to the node M, and another plate is electrically connected to the first reset voltage terminal VGL1; a second electrode of the thirty-ninth transistor M39 is electrically connected to the second control terminal BCK2, a control electrode of the thirty-ninth transistor M39 is electrically connected to the node M, and a first electrode of the thirty-ninth transistor M39 is electrically connected to the first node P.

For example, the second sub-circuit 2 includes a fortieth transistor M40 and a forty-first transistor M41. The fortieth transistor M40 and the forty-first transistor M41 are connected in series, a control electrode of the fortieth transistor M40 and a control electrode of the forty-first transistor M41 are electrically connected to the second control terminal BCK2, a first electrode of the forty-first transistor M41 is electrically connected to the first pull-up node Q1, and a second electrode of the fortieth transistor M40 is electrically connected to the first node P.

Of course, the second sub-circuit 2 can also only include the fortieth transistor M40. The control electrode of the fortieth transistor M40 is electrically connected to the second control terminal BCK2, the first electrode of the fortieth transistor M40 is electrically connected to the first pull-up node Q1, and a second electrode of the fortieth transistor M40 is electrically connected to the first node P.

FIG. 12 exemplarily illustrates a circuit diagram of a second black insertion input circuit. As shown in FIG. 12, the second black insertion input circuit 13b is electrically connected to the first node, the second control terminal BCK2 and the second pull-up node Q2, and is configured to write the signal of the first node into the second pull-up node Q2 under the control of the signal of the second control terminal BCK2.

For example, the second black insertion input circuit 13b includes the fortieth transistor M40 and the forty-first transistor M41. The fortieth transistor M40 and the forty-first transistor M41 are connected in series, and the control electrode of the fortieth transistor M40 and the control electrode of the forty-first transistor M41 are connected to the second control terminal BCK2.

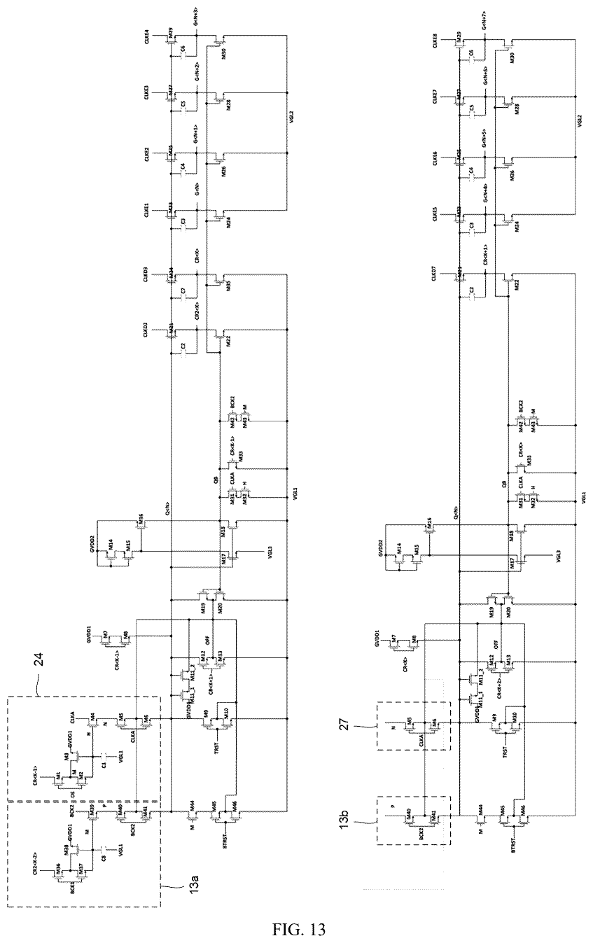

FIG. 13 exemplarily illustrates a circuit diagram of a shift register. As shown in FIG. 12 and FIG. 13, the second black insertion input circuit 13b takes the signal of the first node P in the first black insertion input circuit 13a as the input signal, which is equivalent to the second scanning unit MD2 sharing the first sub-circuit 1 in the first scanning unit MD1, thereby reducing the circuit complexity of the shift register.

Of course, it is also possible that the second black insertion input circuit 13b includes the first sub-circuit 1 and the second sub-circuit 2. At this time, it is equivalent to the first scanning unit MD1 sharing the first sub-circuit 1 in the second scanning unit MD2.

For example, the first sub-circuit 1 is electrically connected to the first black insertion input terminal CR2<K−2>, the first control terminal BCK1, the second voltage terminal V2 and the second node, and is configured to write the signal of the second voltage terminal V2 into the second node under the control of the signals of the first black insertion input terminal CR2<K−2> and the first control terminal BCK1. The second sub-circuit 2 is electrically connected to the second control terminal BCK2, the first node and the second pull-up node Q2, and is configured to write the signal of the first node into the second pull-up node Q2 under the control of the signal of the second control terminal BCK2. The first black insertion input circuit 13a is electrically connected to the first node, the second control terminal BCK2 and the first pull-up node Q1, and is configured to write the signal of the first node into the first pull-up node Q1 under the control of the signal of the second control terminal BCK2.

In addition, when the first scanning unit MD1 includes the first blanking circuit 24, the second scanning unit MD2 can further include a second blanking circuit, which may share part of the structure of the first blanking circuit 24. As shown in FIG. 13, the second blanking circuit is electrically connected to the node N, the fourth voltage terminal CLKA and the second pull-up node Q2, and is configured to write the signal of the node N into the second pull-up node Q2 under the control of the signal of the fourth voltage terminal CLKA.

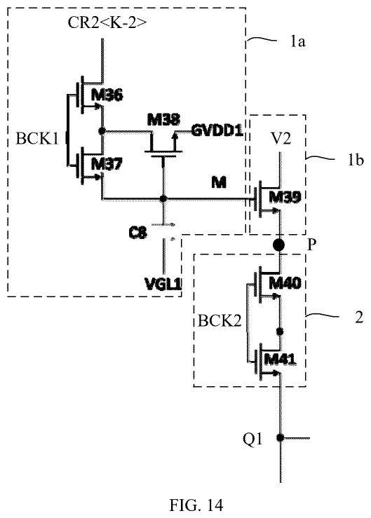

FIG. 14 exemplarily illustrates a circuit diagram of a first black insertion input circuit. As shown in FIG. 14, the first sub-circuit 1 can include a third sub-circuit la and a fourth sub-circuit 1b.

The third sub-circuit la is electrically connected to the first black insertion input terminal CR2<K−2>, the first control terminal BCK1 and the second node, and is configured to write the signal of the first black insertion input terminal CR2<K−2> into the second node under the control of the signal of the first control terminal BCK1.

The fourth sub-circuit 1b is electrically connected to the second node, the second voltage terminal V2, the second control terminal BCK2 and the first pull-up node Q1, and is configured to write the signal of the second voltage terminal V2 into the first pull-up node Q1 under the control of the signals of the second node and the second control terminal BCK2.

Continuing to refer to FIG. 7, the first scanning unit MD1 can further include a first black insertion reset circuit 19. The first black insertion reset circuit 19 is electrically connected to the first pull-up node Q1, the node M, the black insertion reset control terminal BTRST and the first reset voltage terminal VGL1, and is configured to write the signal of the first reset voltage terminal VGL1 into the first pull-up node under the control of the signals of the node M and the black insertion reset control terminal BTRST.

For example, the first black insertion reset circuit 19 includes a forty-fourth transistor M44, a forty-fifth transistor M45 and a forty-sixth transistor M46. The forty-fourth transistor M44, the forty-fifth transistor M45 and the forty-sixth transistor M46 are sequentially connected in series, a control electrode of the forty-fourth transistor M44 is electrically connected to the node M, and a control electrode of the forty-fifth transistor M45 and a control electrode of the forty-sixth transistor M46 are electrically connected to the black insertion reset control terminal BTRST.

The first scanning unit MD1 can further include a fifth reset circuit 21. The fifth reset circuit 21 is electrically connected to the second control terminal BCK2, the node M, the first pull-down node QB1 and the first reset voltage terminal VGL1, and is configured to write the signal of the first reset voltage terminal VGL1 into the first pull-down node QB1 under the control of the signals of the second control terminal BCK2 and the node M.

For example, the fifth reset circuit 21 includes a forty-second transistor M42 and a forty-third transistor M43. The forty-second transistor M42 and the forty-third transistor M43 are connected in series, a gate of the forty-second transistor M42 is electrically connected to the second control terminal BCK2, and a gate of the forty-third transistor M43 is electrically connected to the node M.

The first scanning unit MD1 can further include a leakage prevention circuit 25. The leakage prevention circuit 25 is electrically connected to the first voltage terminal GVDD1, the first pull-up node Q1, the first black insertion input circuit 13, the first blanking circuit 24, the first black insertion reset circuit 19, the first reset circuit 20 and the first noise reduction circuit 18, and is configured to control the signal of the first voltage terminal GVDD1 under the signal of the first pull-up node Q1.

For example, the leakage prevention circuit 25 includes an eleventh transistor M11. A control electrode of the eleventh transistor M11 is electrically connected to the first pull-up node Q1, and a first electrode of the eleventh transistor M11 is connected between the thirty-sixth transistor M36 and the thirty-seventh transistor M37, between the fifth transistor M5 and the sixth transistor M6, between the ninth transistor M9 and the tenth transistor M10, between the forty-fifth transistor M45 and the forty-sixth transistor M46, between the twelfth transistor M12 and the thirteenth transistor M13, and between the nineteenth transistor M19 and the twentieth transistor M20.

The plurality of shift registers in the gate driving circuit can include a plurality of first shift registers and a plurality of second shift registers, which are alternately arranged and cascaded. Hereinafter, the connection relationship of each shift register will be explained by taking the connection relationship of the first shift register and the second shift register arranged in cascade as an example.

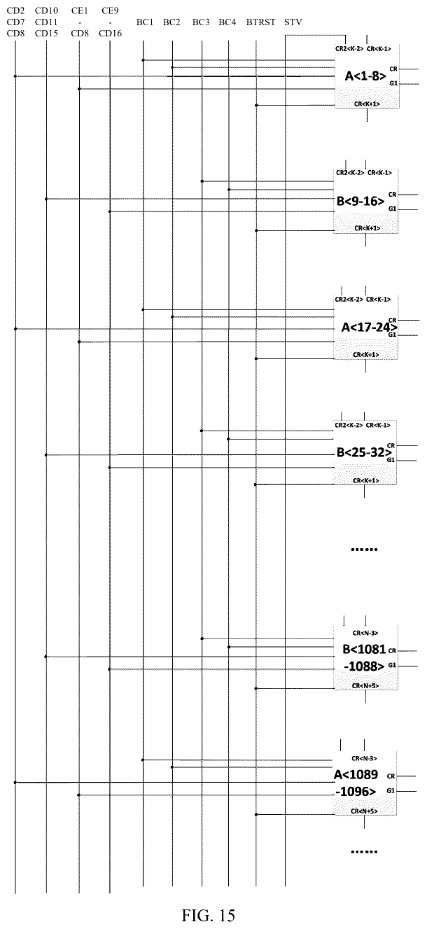

FIG. 15 exemplarily illustrates a block diagram of a gate driving circuit. In FIG. 15, A represents a first shift register, B represents a second shift register, A<1-8> refers to the first shift register electrically connected to a first row of sub-pixels PX to an eighth row of sub-pixels PX, and B<9-16> refers to the second shift register electrically connected to a ninth row of sub-pixels PX to a sixteenth row of sub-pixels PX, and the like. First output terminals and second output terminals in the first shift register A and the second shift register B are both represented by G1. CD1 to CD8 refer to black insertion clock signal lines with serial numbers between CD1 and CD8, including, for example, a second black insertion clock signal line CD2, a third black insertion clock signal line CD3, a sixth black insertion clock signal line CD6 and a seventh black insertion clock signal line CD7. And so on, other labels will not be explained here.

For example, as shown in FIG. 15, the gate driving circuit includes a first control signal line BC1, a second control signal line BC2, a third control signal line BC3 and a fourth control signal line BC4, and further includes a second black insertion clock signal line CD2, a third black insertion clock signal line CD3, a sixth black insertion clock signal line CD6, a seventh black insertion clock signal line CD7, a tenth black insertion clock signal line CD10, an eleventh black insertion clock signal line CD11 and a fifteenth black insertion clock signal line CD15, and further includes a first display clock signal line CE1, a second display clock signal line CE2, a third display clock signal line CE3, a fourth display clock signal line CE4, a fifth display clock signal line CE5, a sixth display clock signal line CE6, a seventh display clock signal line CE7, an eighth display clock signal line CE8, a ninth display clock signal line CE9, a tenth display clock signal line CE10, an eleventh display clock signal line CE11, a twelfth display clock signal line CE12, a thirteenth display clock signal line CE13, a fourteenth display clock signal line CE14, a fifteenth display clock signal line CE15 and a sixteenth display clock signal line CE16. The first control signal line BC1 is electrically connected to the first control terminal BCK1 of the first shift register, the second control signal line BC2 is electrically connected to the second control terminal BCK2 of the first shift register and the second voltage terminal V2, the third control signal line BC3 is electrically connected to the first control terminal BCK1 of the second shift register, and the fourth control signal line BC4 is electrically connected to the second control terminal BCK2 of the second shift register and the second voltage terminal V2. The second black insertion clock signal line CD2 is electrically connected to the second shift signal terminal CLKD2 of the first shift register, the third black insertion clock signal line CD3 is electrically connected to the first shift signal terminal CLKD3 of the first shift register, and the seventh black insertion clock signal line CD7 is electrically connected to the third shift signal terminal CLKD7 of the first shift register. The tenth black insertion clock signal line CD10 is electrically connected to the second shift signal terminal CLKD2 of the second shift register, the eleventh black insertion clock signal line CD11 is electrically connected to the first shift signal terminal CLKD3 of the second shift register, and the fifteenth black insertion clock signal line CD15 is electrically connected to the third shift signal terminal CLKD7 of the second shift register. The four first output circuits 15 of the first shift register are respectively electrically connected to the first display clock signal line CE1, the second display clock signal line CE2, the third display clock signal line CE3 and the fourth display clock signal line CE4, and the four first output circuits 15 of the second shift register are respectively electrically connected to the fifth display clock signal line CE5, the sixth display clock signal line CE6, the seventh display clock signal line CE7 and the eighth display clock signal line CE8.

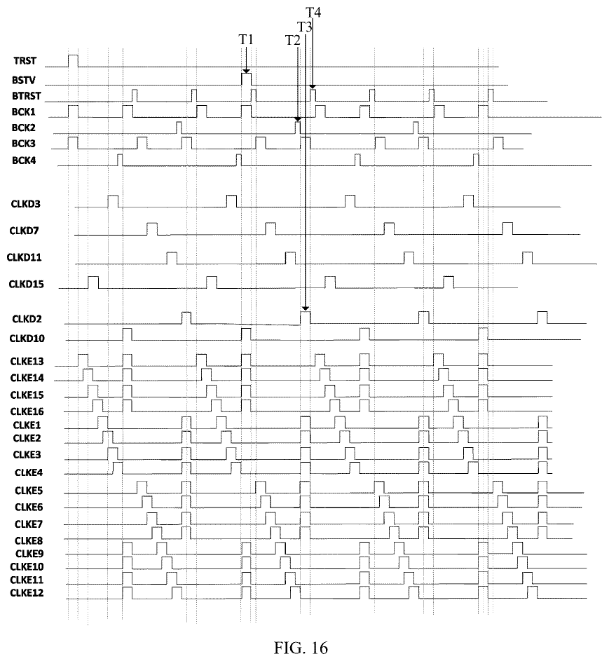

FIG. 16 exemplarily illustrates a timing diagram of a gate driving circuit. As shown in FIG. 16, the black insertion driving stage of the gate driving circuit includes a first stage T1, a second stage T2, a third stage T3 and a fourth stage T4.

In the first stage T1, the BSTV (the first black insertion input terminal CR2<K−2>) and the first control terminal BCK1 are both high level signals, and the black insertion input circuit 13 writes a high level signal at the node M.

In the second stage T2, the second control terminal BCK2 is a high level signal, and the black insertion input circuit 13 writes the high level signal of the second voltage terminal V2 (the second control terminal BCK2) into the first pull-up node Q1 and the second pull-up node Q2 under the control of the signal of the node M.

In the third stage T3, the first output circuit 15 is turned on under the control of the high level signal of the first pull-up node Q1, and the second output circuit 18 is turned on under the control of the high level signal of the second pull-up node Q2. Each first signal terminal (CLKE1, CLKE2, CLKE3, CLKE4, CLKE5, CLKE6, CLKE7 and CLKE8) is a high level signal, so that both the first output terminal and the second output terminal output high-level signals to control the pixel driving circuit P1 to write black data signals.

In the fourth stage T4, the first black insertion reset control terminal BTRST is a high level signal, and the first black insertion reset circuit 19 is turned on under the control of the high level signal of the first black insertion reset control terminal BTRST, so that the signal of the first reset voltage terminal VGL1 is written into the first pull-up node Q1 and the second pull-up node Q2 to reset the first pull-up node Q1 and the second pull-up node Q2.

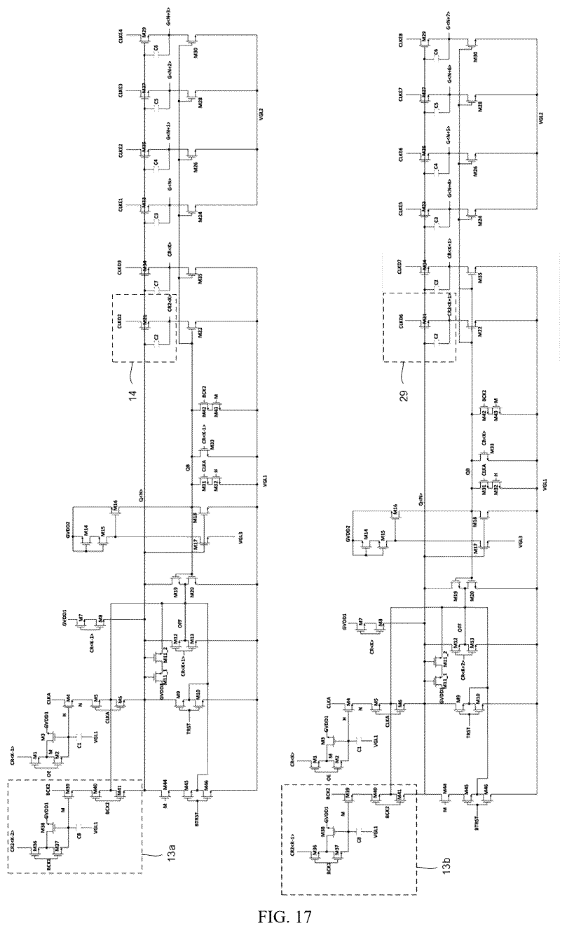

FIG. 17 exemplarily illustrates a circuit diagram of a shift register. As shown in FIG. 17, the first black insertion input circuit 13a is electrically connected to the first black insertion input terminal CR2<K−2>, the first control terminal BCK1, the second control terminal BCK2, the second voltage terminal V2 and the first pull-up node Q1, and is configured to write the signal of the second voltage terminal V2 into the first pull-up node Q1 under the control of the signals of the first black insertion input terminal CR2<K−2>, the first control terminal BCK1 and the second control terminal BCK2.

The second black insertion input circuit 13b is electrically connected to the second black insertion input terminal, the first control terminal BCK1, the second control terminal BCK2, the second voltage terminal V2 and the second pull-up node Q2, and is configured to write the signal of the second voltage terminal V2 into the second pull-up node Q2 under the control of the signals of the second black insertion input terminal, the first control terminal BCK1 and the second control terminal BCK2.

The second scanning unit MD2 further includes a second black insertion shift circuit. The second black insertion shift circuit is electrically connected to the second pull-up node Q2, a fourth shift signal terminal and a fourth shift output terminal, and is configured to write a signal of the fourth shift signal terminal into the fourth shift output terminal under the control of the signal of the second pull-up node Q2.

The plurality of shift registers in the gate driving circuit can include a plurality of first shift registers and a plurality of second shift registers, which are alternately arranged and cascaded. Hereinafter, the connection relationship of each shift register will be explained by taking the connection relationship of the first shift register and the second shift register arranged in cascade as an example.

The second shift output terminal CR2<K> of the first shift register is electrically connected to the first black insertion input terminal CR2<K−2> of the second shift register, and the fourth shift output terminal of the first shift register is electrically connected to the second black insertion input terminal of the second shift register. In this way, the number of scanning units spanned by the black insertion driving modules when cascaded is less and the wiring is simpler.

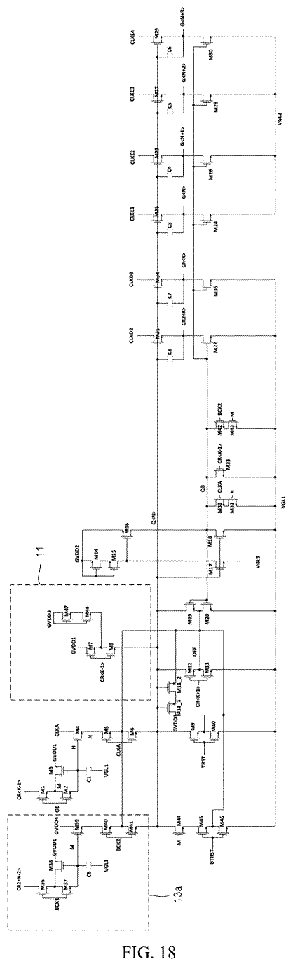

FIG. 18 exemplarily illustrates a circuit diagram of another shift register. As shown in FIG. 18, the first display input circuit 11 can include a seventh transistor M7, an eighth transistor M8, a forty-seventh transistor M47 and a forty-eighth transistor M48. The seventh transistor M7 and the eighth transistor M8 are connected in series, and a control electrode of the seventh transistor M7 and a control electrode of the eighth transistor M8 are electrically connected to the first display input terminal CR<K−1>, a second electrode of the seventh transistor M7 is electrically connected to the first voltage terminal GVDD1, and a first electrode of the eighth transistor M8 is electrically connected to the first pull-up node Q1. The forty-seventh transistor M47 and the forty-eighth transistor M48 are connected in series, a control electrode of the forty-seventh transistor M47, a control electrode of the forty-eighth transistor M48 and a second electrode of the forty-seventh transistor are electrically connected to a voltage line GVDD3, where the voltage line GVDD3 is supplied with a constant high level signal, and the first electrode of the forty-eighth transistor M48 is connected between the seventh transistor M7 and the eighth transistor M8.

The above is only the specific embodiments of the present disclosure, but the protection scope of the present disclosure is not limited to this. Any skilled person familiar with this technical field can easily think of changes or replacements within the technical scope disclosed in the present disclosure, which should be covered within the protection scope of the present disclosure. Therefore, the protection scope of the present disclosure should be based on the protection scope of the claims.

1. A shift register, comprising a first scanning unit, wherein the first scanning unit comprises a first display input circuit, a first display shift circuit, a black insertion input circuit, a first black insertion shift circuit and a first output circuit, wherein
the first display input circuit is electrically connected to a first display input terminal, a first voltage terminal and a first pull-up node, and is configured to write a signal of the first voltage terminal into the first pull-up node under the control of a signal of the first display input terminal;
the first display shift circuit is electrically connected to the first pull-up node, a first shift signal terminal and a first shift output terminal, and is configured to write a signal of the first shift signal terminal into the first shift output terminal under the control of a signal of the first pull-up node;
the black insertion input circuit is electrically connected to a first black insertion input terminal, a first control terminal, a second control terminal, a second voltage terminal and the first pull-up node, and is configured to write a signal of the second voltage terminal into the first pull-up node under the control of signals of the first black insertion input terminal, the first control terminal and the second control terminal;
the first black insertion shift circuit is electrically connected to the first pull-up node, a second shift signal terminal and a second shift output terminal, and is configured to write a signal of the second shift signal terminal into the second shift output terminal under the control of the signal of the first pull-up node; and
the first output circuit is electrically connected to the first pull-up node, a first signal terminal and a first output terminal, and is configured to write a signal of the first signal terminal into the first output terminal under the control of the signal of the first pull-up node.

2. The shift register according to claim 1, further comprising a second scanning unit, wherein the second scanning unit comprises a second display input circuit, a second display shift circuit and a second output circuit, wherein
the second display input circuit is electrically connected to the first shift output terminal, the first voltage terminal and a second pull-up node, and is configured to write a signal of the first voltage terminal into the second pull-up node under the control of a signal of the first shift output terminal;
the second display shift circuit is electrically connected to the second pull-up node, a third shift signal terminal and a third shift output terminal, and is configured to write a signal of the third shift signal terminal into the third shift output terminal under the control of a signal of the second pull-up node;
the second output circuit is electrically connected to the second pull-up node, a second signal terminal and a second output terminal, and is configured to write a signal of the second signal terminal into the second output terminal under the control of the signal of the second pull-up node; and
the black insertion input circuit is electrically connected to the first pull-up node and the second pull-up node at the same time, and is further configured to write a signal at the second pull-up node.

3. The shift register according to claim 2, wherein the black insertion input circuit comprises a first black insertion input circuit and a second black insertion input circuit, wherein the first black insertion input circuit is electrically connected to the first pull-up node, and is configured to write a signal at the first pull-up node; and the second black insertion input circuit is electrically connected to the second pull-up node, and is configured to write a signal at the second pull-up node.

4. The shift register according to claim 3, wherein at a same time, the signal written by the first black insertion input circuit at the first pull-up node is the same as the signal written by the second black insertion input circuit at the second pull-up node.

5. The shift register according to claim 4, wherein
the first black insertion input circuit is electrically connected to the first black insertion input terminal, the first control terminal, the second control terminal, the second voltage terminal and the first pull-up node, and is configured to write the signal of the second voltage terminal into the first pull-up node under the control of the signals of the first black insertion input terminal, the first control terminal and the second control terminal; and
the second black insertion input circuit is electrically connected to the first black insertion input terminal, the first control terminal, the second control terminal, the second voltage terminal and the second pull-up node, and is configured to write the signal of the second voltage terminal into the second pull-up node under the control of the signals of the first black insertion input terminal, the first control terminal and the second control terminal.

6. The shift register according to claim 4, wherein the first black insertion input circuit comprises a first sub-circuit and a second sub-circuit, wherein
the first sub-circuit is electrically connected to the first black insertion input terminal, the first control terminal, the second voltage terminal and a first node, and is configured to write the signal of the second voltage terminal into the first node under the control of signals of the first black insertion input terminal and the first control terminal;
the second sub-circuit is electrically connected to the second control terminal, the first node and the first pull-up node, and is configured to write a signal of the first node into the first pull-up node under the control of the signal of the second control terminal; and
the second black insertion input circuit is electrically connected to the first node, the second control terminal and the second pull-up node, and is configured to write the signal of the first node into the second pull-up node under the control of the signal of the second control terminal.

7. The shift register according to claim 4, wherein the second black insertion input circuit comprises a first sub-circuit and a second sub-circuit, wherein
the first sub-circuit is electrically connected to the first black insertion input terminal, the first control terminal, the second voltage terminal and a second node, and is configured to write the signal of the second voltage terminal into the second node under the control of signals of the first black insertion input terminal and the first control terminal;
the second sub-circuit is electrically connected to the second control terminal, a first node and the second pull-up node, and is configured to write a signal of the first node into the second pull-up node under the control of the signal of the second control terminal; and
the first black insertion input circuit is electrically connected to the first node, the second control terminal and the first pull-up node, and is configured to write the signal of the first node into the first pull-up node under the control of the signal of the second control terminal.

8. The shift register according to claim 3, wherein the first black insertion input circuit is electrically connected to the first black insertion input terminal, the first control terminal, the second control terminal, the second voltage terminal and the first pull-up node, and is configured to write the signal of the second voltage terminal into the first pull-up node under the control of the signals of the first black insertion input terminal, the first control terminal and the second control terminal;
the second black insertion input circuit is electrically connected to the second black insertion input terminal, the first control terminal, the second control terminal, the second voltage terminal and the second pull-up node, and is configured to write the signal of the second voltage terminal into the second pull-up node under the control of signals of the second black insertion input terminal, the first control terminal and the second control terminal; and
the second scanning unit further comprises a second black insertion shift circuit, wherein the second black insertion shift circuit is electrically connected to the second pull-up node, a fourth shift signal terminal and a fourth shift output terminal, and is configured to write a signal of the fourth shift signal terminal into the fourth shift output terminal under the control of the signal of the second pull-up node.

9. The shift register according to claim 4, wherein the second voltage terminal is electrically connected to the second control terminal, or the second voltage terminal is disconnected from the second control terminal.

10. The shift register according to claim 6, wherein the first sub-circuit comprises a third sub-circuit and a fourth sub-circuit, wherein
the third sub-circuit is electrically connected to the first black insertion input terminal, the first control terminal and the second node, and is configured to write the signal of the first black insertion input terminal into the second node under the control of the signal of the first control terminal; and
the fourth sub-circuit is electrically connected to the second node, the second voltage terminal, the second control terminal and the first pull-up node, and is configured to write the signal of the second voltage terminal into the first pull-up node under the control of signals of the second node and the second control terminal.

11. The shift register according to claim 10, wherein the first scanning unit further comprises a first black insertion reset circuit, wherein the first black insertion reset circuit is electrically connected to the first pull-up node, the second node, a black insertion reset control terminal and a first reset voltage terminal, and is configured to write a signal of the first reset voltage terminal into the first pull-up node under the control of signals of the second node and the black insertion reset control terminal.

12. The shift register according to claim 10, wherein the first scanning unit further comprises a first pull-down circuit and a first noise reduction circuit, wherein
the first pull-down circuit is electrically connected to the first pull-up node, a first reset voltage terminal and a first pull-down node, and is configured to write a signal of the first reset voltage terminal into the first pull-down node under the control of the signal of the first pull-up node; and
the first noise reduction circuit is electrically connected to the first pull-down node, the first reset voltage terminal and the second shift output terminal, and is configured to write the signal of the first reset voltage terminal into the second shift output terminal under the control of a signal of the first pull-down node.

13. The shift register according to claim 12, further comprising a fifth reset circuit, wherein the fifth reset circuit is electrically connected to the second control terminal, the second node, the first reset voltage terminal and the first pull-down node, and is configured to write the signal of the first reset voltage terminal into the first pull-down node under the control of signals of the second node and the second control terminal.

14. A gate driving circuit, comprising a plurality of shift registers according to claim 1, wherein the plurality of shift registers are arranged in cascade.

15. The gate driving circuit according to claim 14, wherein the plurality of the shift registers comprise a first shift register and a second shift register which are arranged in cascade, wherein when each of the plurality of the shift registers comprises a first display shift circuit, a second display shift circuit and a first black insertion shift circuit, a second shift output terminal of the first shift register is electrically connected to a first black insertion input terminal of the second shift register, and a third shift output terminal of the first shift register is connected to a first display input terminal of the second shift register.

16. The gate driving circuit according to claim 14, wherein the plurality of the shift registers comprise a first shift register and a second shift register which are arranged in cascade, wherein when each of the plurality of the shift registers comprises a first display shift circuit, a second display shift circuit, a first black insertion shift circuit and a second black insertion shift circuit, a third shift output terminal of the first shift register is electrically connected to a first display input terminal of the second shift register, a second shift output terminal of the first shift register is electrically connected to a first black insertion input terminal of the second shift register, and a fourth shift output terminal of the first shift register is electrically connected to a second black insertion input terminal of the second shift register.

17. The gate driving circuit according to claim 14, wherein the gate driving circuit comprises a plurality of gate lines, and the first scanning unit comprises a plurality of first output circuits, wherein first output terminals of the plurality of first output circuits are respectively electrically connected to different gate lines; and/or, the second scanning unit comprises a plurality of second output circuits, wherein second output terminals of the plurality of second output circuits are respectively electrically connected to different gate lines, wherein the first output terminals and the second output terminals are electrically connected to different gate lines.

18. The gate driving circuit according to claim 17, wherein the first scanning unit comprises four first output circuits, and the second scanning unit comprises four second output circuits.

19. A display panel, comprising the gate driving circuit according to claim 14.

20. A display device, comprising the display panel according to claim 19.
